(19) United States
(12) Patent Application Publication
(10) Pub. No.: US 2025/0293140 A1
(43) Pub. Date: Sep. 18, 2025

(54) SEMICONDUCTOR DEVICE

(71) Applicant: Kioxia Corporation, Tokyo (JP)

(72) Inventor: Satoru ITAKURA, Machida Tokyo (JP)

(73) Assignee: Kioxia Corporation, Tokyo (JP)

(21) Appl. No.: 18/973,658

(22) Filed: Dec. 9, 2024

(30) Foreign Application Priority Data
Mar. 18, 2024 (JP) 2024-041973

(51) Int. Cl. H01L 23/498; H01L 23/00

(52) U.S. Cl. CPC H01L 23/49838; H01L 24/48; H01L 2224/48229

(57) ABSTRACT

According to one embodiment, a semiconductor device includes a semiconductor chip and a wiring board. The wiring board includes a plurality of bonding fingers electrically connectable to the semiconductor chip on a first face of the wiring board, and a power supply layer and a ground layer between the first face and a second face located on an opposite side of the first face. First bonding fingers connected to the ground layer and second bonding fingers connected to the power supply layer are alternately arranged. One of the first bonding fingers disposed at both ends is a dummy terminal that is not connected to the semiconductor chip.

### CROSS-REFERENCE TO RELATED APPLICATIONS

This application is based upon and claims the benefit of priority from Japanese Patent Application No. 2024-041973, filed on Mar. 18, 2024; the entire contents of which are incorporated herein by reference.

### FIELD

Embodiments described herein relate generally to a semiconductor device.

### BACKGROUND

A semiconductor device in which a semiconductor chip has been mounted on a wiring board has been proposed. A plurality of bonding fingers electrically connected to the semiconductor chip is arranged on a mounting surface of the wiring board. The bonding fingers include a first bonding finger that supplies a ground potential to the semiconductor chip and a second bonding finger that supplies a power supply voltage.

In this case, a metal component is eluted from the second bonding finger in some cases. Such elution of the metal component remarkably occurs in, for example, the high accelerated temperature and humidity stress test (HAST). The eluted metal component serves as a leakage path, and a short circuit occurs between adjacent bonding fingers in some cases.

### BRIEF DESCRIPTION OF THE DRAWINGS

FIG. 1 is a schematic sectional view illustrating an example of a configuration of a semiconductor device according to an embodiment;

FIG. 2 is a schematic top view illustrating an example of the configuration of the semiconductor device according to the embodiment;

FIG. 3 is a sectional view taken along line A-A of FIG. 2;

FIG. 4 is a top view schematically illustrating a state of eluting a metal component at a time when the HAST has been conducted on the semiconductor device according to the embodiment;

FIG. 5 is a partial top view illustrating a configuration around an opening of the semiconductor device according to a first variation;

FIG. 6 is a partial top view illustrating a configuration around an opening of the semiconductor device according to a second variation;

FIG. 7 is a partial top view illustrating a configuration around an opening of the semiconductor device according to a third variation;

FIG. 8 is a partial top view illustrating a configuration around an opening of the semiconductor device according to a fourth variation; and

FIG. 9 is a top view schematically illustrating a state of eluting a metal component at a time when the HAST has been conducted on the semiconductor device according to a comparative example.

### DETAILED DESCRIPTION

In general, according to one embodiment, a semiconductor device includes a semiconductor chip and a wiring board. The semiconductor chip and an insulating layer having an opening are disposed on a first face of the wiring board. The wiring board includes a plurality of bonding fingers, a power supply layer, and a ground layer, the plurality of bonding fingers being arranged along a first direction that is a longitudinal direction of the opening and being electrically connectable to the semiconductor chip in the opening, the power supply layer and the ground layer being between the first face and a second face located on an opposite side of the first face, the power supply layer supplying a power supply voltage to the semiconductor chip, and the ground layer supplying a ground potential to the semiconductor chip. The plurality of bonding fingers includes first bonding fingers and second bonding fingers that are alternately arranged to be spaced apart from each other by an equal distance, the first bonding fingers being connected to the ground layer, the second bonding fingers being connected to the power supply layer, each of two third bonding fingers disposed at both ends in the first direction of the opening among the plurality of bonding fingers is the first bonding finger, and one of the two third bonding fingers is a dummy terminal that is not connected to the semiconductor chip.

Exemplary embodiments of a semiconductor device will be described below in detail with reference to the accompanying drawings. Note that the present invention is not limited to the embodiments described below. Furthermore, components in the embodiments described below include components that those skilled in the art could easily conceive of, or substantially identical components.

### Embodiments

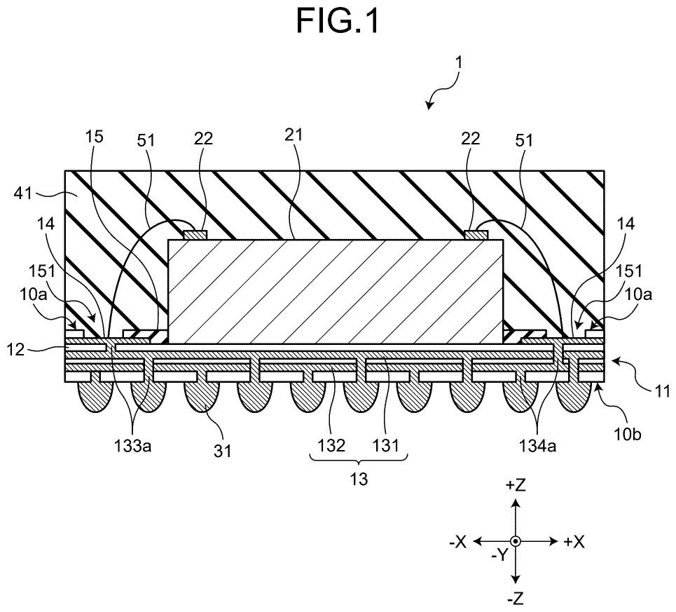

Embodiments will be described below in detail with reference to FIGS. 1 to 4.

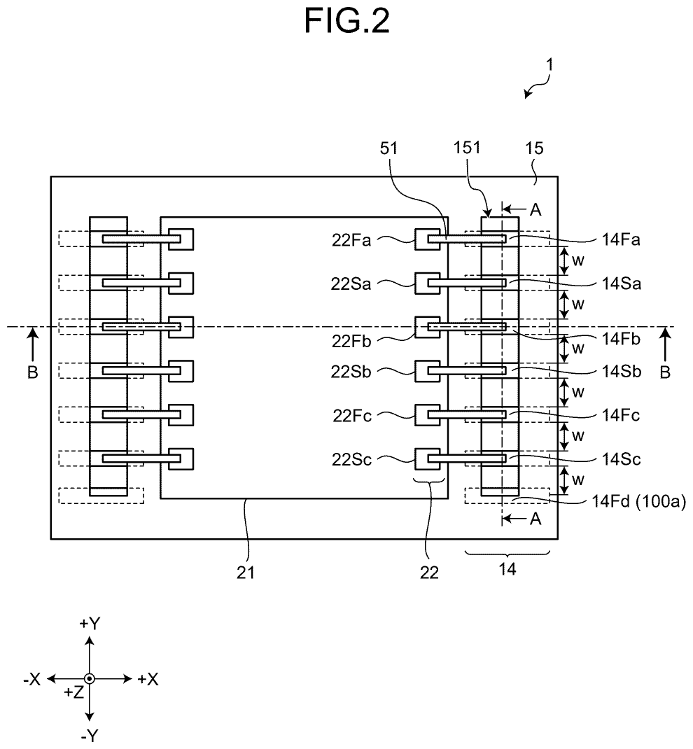

FIG. 1 is a schematic sectional view illustrating an example of a configuration of a semiconductor device 1 according to an embodiment. FIG. 1 is also a sectional view taken along line B-B of FIG. 2.

Note that, herein, it is assumed that a side of a semiconductor chip 21 of the semiconductor device 1 is an upper side, and a side of a wiring board 11 is a lower side. In addition, an upward/downward direction of the semiconductor device 1 is referred to as a Z direction. Furthermore, an X direction is a direction along an orientation of a face of the wiring board 11 described later. It is also assumed that a direction that intersects the X direction and the Z direction is a Y direction. The X direction, the Y direction, and the Z direction may be orthogonal to each other. It is also assumed that a direction indicated by one arrow of each of an X axis, a Y axis, and a Z axis is a positive direction, and an opposite direction is a negative direction. The X direction is an example of a second direction, and the Y direction is an example of a first direction.

As illustrated in FIG. 1, the semiconductor device 1 is configured as a package in which the semiconductor chip 21 has been sealed. The semiconductor device 1 includes the wiring board 11, the semiconductor chip 21, a solder ball 31, a sealing member 41, and a bonding wire 51. On an upper face of the wiring board 11, the semiconductor chip 21 is disposed. The semiconductor chip 21 and the wiring board 11 are connected to each other through the bonding wire 51. On a lower face of the wiring board 11, a plurality of solder balls 31 is disposed. Furthermore, the wiring board 11, the semiconductor chip 21, and the bonding wire 51 are covered with the sealing member 41.

The wiring board 11 includes an insulating layer 12, a wiring layer 13, a bonding finger 14, and a solder resist layer 15.

The insulating layer 12 is, for example, a prepreg made of a carbon fiber, a glass fiber, an aramid fiber, or the like that has been impregnated with a thermosetting resin such as an epoxy resin before curing.

On an upper face of the insulating layer 12, the bonding finger 14 and the solder resist layer 15 are formed in this order. The bonding finger 14 is a terminal that contains a conductive material such as Cu. A plurality of bonding fingers 14 is formed on the upper face of the insulating layer 12. In some bonding fingers 14 of the plurality of bonding fingers 14, a lower face is connected to a via 133a and a power supply layer 131 that will be described later. Furthermore, in other bonding fingers 14, a lower face is connected to a via 134a and a ground layer 132 that will be described later. Moreover, in the plurality of bonding fingers 14, an upper face is configured to be connectable to the bonding wire 51.

The solder resist layer 15 is an insulating layer that protects the plurality of bonding fingers 14. The solder resist layer 15 is formed in the periphery including spacing between adjacent bonding fingers and upper sides of the plurality of bonding fingers 14, and electrically insulates these bonding fingers 14. The solder resist layer 15 includes an opening 151 in positions that overlap the plurality of bonding fingers 14 when viewed in the Z direction. Therefore, at least a portion of each of the bonding fingers 14 is exposed, and this enables connection between the bonding finger 14 and the bonding wire 51. The solder resist layer 15 is an example of an insulating layer.

Note that hereinafter, in the wiring board 11, a face located on a side where the solder resist layer 15 is formed is referred to as a face 10a serving as a first face in some cases. Furthermore, a face located on an opposite side of the face 10a of the wiring board 11, that is, a lower face of the wiring board 11, is referred to as a face 10b serving as a second face in some cases.

The wiring layer 13 contains a conductive material such as Cu. The wiring layer 13 includes the power supply layer 131 and the ground layer 132 that each extend along the X and Y directions between the face 10a and the face 10b. The wiring layer 13 also includes the vias 133a and 134a that extend in the Z direction between the face 10a and the face 10b, and are respectively connected to the power supply layer 131 and the ground layer 132.

Specifically, the power supply layer 131 is connected to the via 133a. The via 133a is exposed on the upper face of the insulating layer 12 and the lower face of the insulating layer 12, and is connected to any of the plurality of bonding fingers 14 and any of the plurality of solder balls 31 described later. This causes the power supply layer 131 to electrically connect the bonding finger 14 and the solder ball 31. The power supply layer 131 supplies any of the plurality of bonding fingers 14 with a power supply voltage that has been supplied from a not-illustrated external device or the like via the solder ball 31.

The ground layer 132 is connected to the via 134a. The via 134a is exposed on the upper face of the insulating layer 12 and the lower face of the insulating layer 12, and is connected to any of the plurality of bonding fingers 14 and any of the plurality of solder balls 31. This causes the ground layer 132 to electrically connect the bonding finger 14 and the solder ball 31. The ground layer 132 supplies any of the plurality of bonding fingers 14 with a ground potential that has been supplied from a not-illustrated external device or the like through the solder ball 31.

On the face 10b of the wiring board 11, the plurality of solder balls 31 is provided to protrude from the face 10b. The plurality of solder balls 31 contains a conductive material such as Sn. One end of the solder ball 31 is connected to, for example, the via 133a or the via 134a, and another end is connected to, for example, a not-illustrated external device or the like. Therefore, the power supply voltage is supplied from the external device or the like to the power supply layer 131 through some solder balls 31 of the plurality of solder balls 31, and the ground potential is supplied from the external device or the like to the ground layer 132 through other solder balls 31.

On the face 10a of the wiring board 11, the semiconductor chip 21 is mounted. The semiconductor chip 21 is a small piece obtained by dicing a silicon substrate or the like. The semiconductor chip 21 is a memory chip of, for example, a non-volatile memory. The semiconductor chip 21 includes an electrode pad 22 that is electrically connected to, for example, the non-volatile memory. The semiconductor chip 21 is disposed on the face 10a in such a way that a face provided with the electrode pad 22 faces upward. The electrode pad 22 contains a metal material such as Cu. The electrode pad 22 is connected to the bonding wire 51. This enables the semiconductor chip 21 to be electrically connected to the plurality of bonding fingers 14 through the bonding wire 51.

The sealing member 41 seals the entire structure on the face 10a, such as the semiconductor chip 21 or the bonding wire 51. The sealing member 41 is, for example, a thermosetting resin such as an epoxy resin or an acrylic resin.

Note that FIG. 1 illustrates an example where a single semiconductor chip 21 is mounted on each semiconductor device, but the number of semiconductor chips 21 to be mounted is not limited to the description above, and is arbitrary. For example, two or more semiconductor chips 21 may be mounted on the face 10a of the wiring board 11.

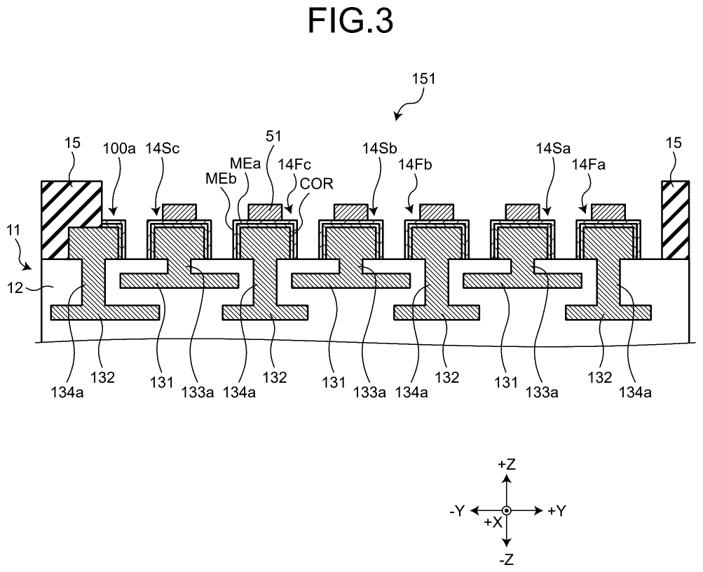

Next, details of connection of the bonding fingers 14 will be described with reference to FIGS. 2 and 3.

FIG. 2 is a schematic top view illustrating an example of a configuration of the semiconductor device 1 according to the embodiment. Note that in FIG. 2, a configuration of the sealing member 41 or the like is omitted.

As illustrated in FIG. 2, the semiconductor device 1 is formed in a roughly rectangular shape when viewed in the Z direction. In a roughly central portion of the semiconductor device 1, the semiconductor chip 21 is disposed. On an upper face of the semiconductor chip 21, a plurality of electrode pads 22 is formed. The electrode pads 22 are disposed in a row along the Y direction, for example, at both ends in the X direction of the semiconductor chip 21.

Not that hereinafter, a configuration located on a positive X direction side in the semiconductor device 1 when viewed from the semiconductor chip 21 will be described, but it is assumed that a negative X direction side has a configuration that is similar to the configuration located on the positive X direction side.

The electrode pads 22 have a configuration in which first electrode pads 22F (22Fa to 22Fc) and second electrode pads 22S (22Sa to 22Sc) are alternately arranged. For example, in the example of FIG. 2, the first electrode pad 22Fa, the second electrode pad 22Sa, the first electrode pad 22Fb, the second electrode pad 22Sb, the first electrode pad 22Fc, and the second electrode pad 22Sc are disposed in this order from a positive Y direction side toward a negative Y direction side. Each of the first electrode pads 22Fa to 22Fc and the second electrode pads 22Sa to 22Sc is connected to the bonding wire 51.

Around the semiconductor chip 21 when viewed in the Z direction, the solder resist layer 15 is disposed. The solder resist layer 15 includes the opening 151 on an outer side in the X direction of the semiconductor chip 21. The opening 151 has a rectangular shape having a longitudinal direction in the Y direction.

In a position that corresponds to the opening 151 when viewed in the Z direction, the plurality of bonding fingers 14 is disposed in a row along the Y direction. The plurality of bonding fingers 14 is formed in a finger shape that extends in the X direction. As illustrated in FIG. 2, both ends in the X direction of the plurality of bonding fingers 14 are covered with the solder resist layer 15. Therefore, in the opening 151, a central portion of each of the bonding fingers 14 is exposed.

More specifically, the plurality of bonding fingers 14 has a configuration in which first bonding fingers 14F (14Fa to 14Fd) and second bonding fingers 14S (14Sa to 14Sc) are alternately arranged to be spaced apart from each other by an equal distance. For example, in the example of FIG. 2, the first bonding finger 14Fa, the second bonding finger 14Sa, the first bonding finger 14Fb, the second bonding finger 14Sb, the first bonding finger 14Fc, the second bonding finger 14Sc, and the first bonding finger 14Fd are disposed in this order at equal intervals W from the positive Y direction side toward the negative Y direction side.

At both ends in the Y direction of the opening 151, two bonding fingers, the first bonding finger 14Fa and the first bonding finger 14Fd, are disposed. In more detail, the first bonding finger 14Fa is disposed at an end in a positive Y direction of the opening 151, and the first bonding finger 14Fd is disposed at an end in a negative Y direction. Stated another way, the number of first bonding fingers 14F (14Fa to 14Fd) that are disposed is larger than the number of second bonding fingers 14S (14Sa to 14Sc) that are disposed. Each of the first bonding finger 14Fa and the first bonding finger 14Fd is an example of a third bonding finger.

The first bonding fingers 14Fa to 14Fc are respectively connected to the first electrode pads 22Fa to 22Fc through the bonding wire 51. Furthermore, the second bonding fingers 14Sa to 14Sc are respectively connected to the second electrode pads 22Sa to 22Sc through the bonding wire 51. On the other hand, the first bonding finger 14Fd is not connected to the bonding wire 51. Stated another way, the first bonding finger 14Fd is a dummy terminal that is not connected to the semiconductor chip 21. In other words, one of the two third bonding fingers is the dummy terminal that is not connected to the semiconductor chip 21. Hereinafter, the first bonding finger 14Fd is referred to as a dummy terminal 100a in some cases.

Note that FIG. 2 illustrates an example where the first bonding fingers 14Fa to 14Fd and the second bonding fingers 14Sa to 14Sc are disposed, but the number of bonding fingers to be disposed is not limited to the description above, and is arbitrary.

FIG. 3 is a sectional view taken along line A-A of FIG. 2. Note that in FIG. 3, configurations of the sealing member 41, the solder balls 31, and the like are omitted.

As illustrated in FIG. 3, in the opening 151, portions of the first bonding fingers 14Fa to 14Fc, the second bonding fingers 14Sa to 14Sc, and the dummy terminal 100a are exposed. At both ends in the Y direction of the opening 151, the solder resist layer 15 is formed. An upper face of the solder resist layer 15 is located on a positive Z direction side of upper faces of the first bonding fingers 14Fa to 14Fc, the second bonding fingers 14Sa to 14Sc, and the dummy terminal 100a.

As illustrated in FIG. 3, in the opening 151, the first bonding fingers 14Fa to 14Fc and the dummy terminal 100a are electrically connected to the ground layer 132 through the via 134a. This causes the ground potential to be supplied to the first bonding fingers 14Fa to 14Fc and the dummy terminal 100a. Furthermore, the second bonding fingers 14Sa to 14Sc are connected to the power supply layer 131 through the via 133a. This causes the power supply voltage to be supplied to the second bonding fingers 14Sa to 14Sc.

Furthermore, as illustrated in FIG. 3, the bonding fingers 14 including the first bonding fingers 14Fa to 14Fc, the second bonding fingers 14Sa to 14Sc, and the dummy terminal 100a have a three-layer structure including a core layer COR, a plated layer MEa, and a plated layer MEb in this order from an inner side.

The core layer COR contains a conductive material such as Cu. The core layer COR can be obtained by performing etching on a Cu layer that has been formed on the insulating layer 12 by using, for example, an evaporation method.

Furthermore, the plated layer MEa contains a conductive material such as Ni. The plated layer MEa is formed by forming the solder resist layer 15 on the core layer COR, and then performing electroplating by using, as an electrode, the core layer COR exposed in the opening 151. In electroplating, plating solution and a plating lead that are not illustrated are used. In performing electroplating, in a state where the core layer COR has been immersed into the plating solution, a predetermined voltage is supplied to the core layer COR by using the plating lead. This causes the plated layer MEa to be formed in a surface portion exposed in the opening 151 of the core layer COR.

The plated layer MEb contains a conductive material such as Au. The plated layer MEb is formed by performing electroplating by using the plated layer MEa as an electrode. The plated layer MEa and the plated layer MEb are formed on the core layer COR, and therefore connection to the bonding wire 51 can be easily established.

Furthermore, as illustrated in FIG. 3, at least a portion in the negative Y direction of the dummy terminal 100a is covered with the solder resist layer 15. In the portion covered with the solder resist layer 15, the plated layers MEa and MEb are not formed. This decreases an exposed area of the core layer COR to be plated, and therefore the consumption of the plating solution can be reduced, and as a result, a manufacturing cost of the semiconductor device 1 can be reduced. Furthermore, in a portion that is not covered with the solder resist layer 15 of the dummy terminal 100a, the plated layer MEa and the plated layer MEb may be omitted. This is because the dummy terminal 100a is not connected to the bonding wire 51.

Incidentally, a variety of tests are conducted on the semiconductor device 1 having the configuration described above before shipment as a product. In the present embodiment, the HAST is described as an example. The HAST is a test for checking reliability of the semiconductor device 1 in a case where the semiconductor device 1 is placed in an accelerating environment. In the HAST, the semiconductor device 1 is set on a not-illustrated test board, and, for example, the power supply voltage and the ground potential are supplied from an external device or the like through the test board. Then, after the test board has been placed in a high-temperature and high-humidity environment during a predetermined time period, a test for electric characteristics or the like is conducted. At this time, a metal component such as Cu is eluted from, for example, the bonding fingers 14 in some cases.

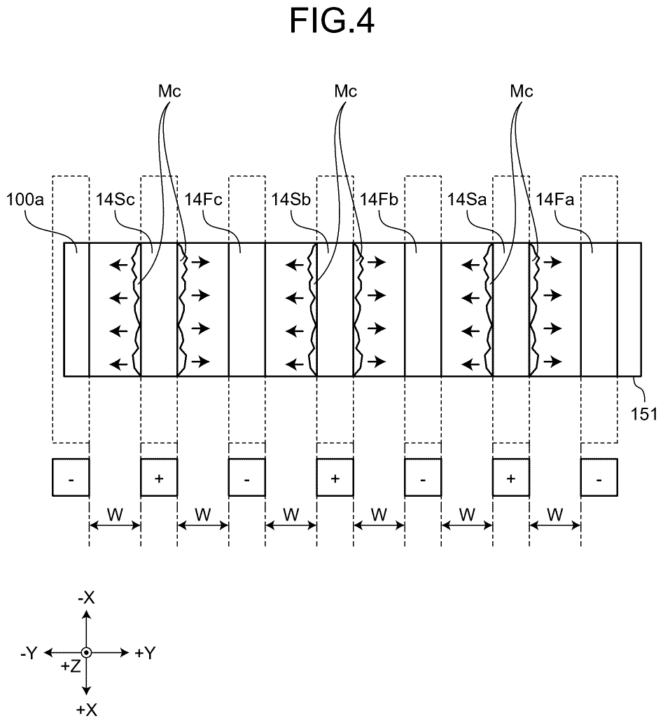

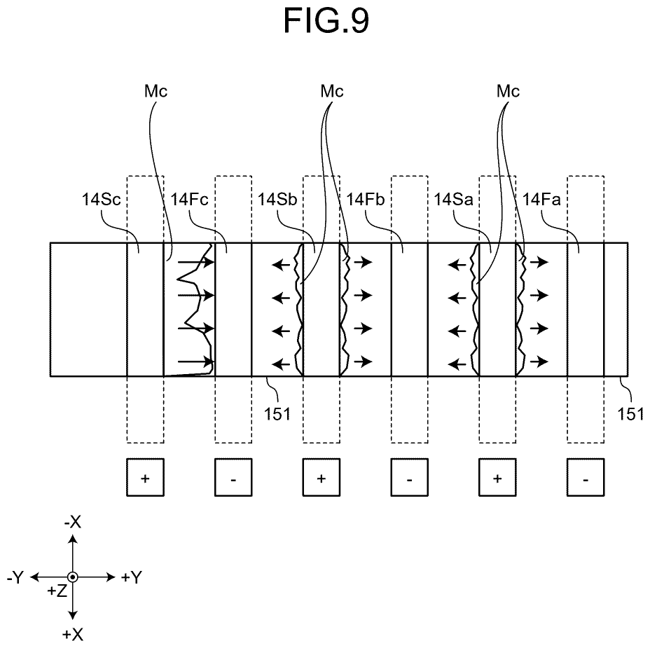

Here, elution of the metal component from the bonding fingers 14 at a time when the HAST has been conducted will be described with reference to FIGS. 4 and 9.

FIG. 4 is a top view schematically illustrating a state of eluting the metal component at a time when the HAST has been conducted on the semiconductor device 1 according to the embodiment. In contrast, FIG. 9 is a top view schematically illustrating a state of eluting the metal component at a time when the HAST has been conducted on the semiconductor device according to a comparative example. Note that in FIGS. 4 and 9, configurations of the bonding wire 51, the sealing member 41, and the like are omitted.

As described above, in the semiconductor device 1 according to the embodiment, the first bonding finger 14Fa and the dummy terminal 100a are disposed at both ends in the Y direction of the opening 151. A central portion along the X direction of the first bonding finger 14Fa is exposed in the opening 151, but a central portion along the X direction of the dummy terminal 100a is at least partially covered with the solder resist layer 15 (see FIGS. 1 to 3). Furthermore, between the first bonding finger 14Fa and the dummy terminal 100a, the first bonding fingers 14Fb to 14Fc and the second bonding fingers 14Sa to 14Sc are alternately disposed to be spaced apart from each other by the interval W. Stated another way, in the semiconductor device 1 according to the embodiment, on both sides in the Y direction of each of the second bonding fingers 14Sa to 14Sc, either the first bonding finger or the dummy terminal 100a is disposed.

Specifically, as illustrated in FIG. 4, for example, the first bonding finger 14Fa and the first bonding finger 14Fb are disposed on both sides in the Y direction of the second bonding finger 14Sa, the first bonding finger 14Fb and the first bonding finger 14Fc are disposed on both sides in the Y direction of the second bonding finger 14Sb, and the first bonding finger 14Fc and the dummy terminal 100a are disposed on both sides in the Y direction of the second bonding finger 14Sc.

If the HAST is conducted on the semiconductor device 1, as described above, Cu ions Mc are eluted from portions exposed in the opening 151 of the second bonding fingers 14Sa to 14Sc in some cases, as illustrated in FIG. 4. The eluted Cu ions Mc move from each of the second bonding fingers 14Sa to 14Sc toward each of the first bonding fingers 14Fa to 14Fc and the dummy terminal 100a that sandwich the second bonding fingers 14Sa to 14Sc from both sides in the Y direction. Cu ions Mc can be eluted, as described above, due to a potential difference between the second bonding fingers 14Sa to 14Sc that are supplied with the power supply voltage having a high potential (illustrated as +), and the first bonding fingers 14Fa to 14Fc and the dummy terminal 100a that are supplied with the ground potential having a low potential (illustrated as −), and moisture in an atmosphere.

At this time, an amount of Cu ions Mc eluted from each of the second bonding fingers 14Sa to 14Sc is equal on both sides in the Y direction of a corresponding second bonding finger. Specifically, as illustrated in, for example, FIG. 4, an amount of Cu ions Mc eluted from the second bonding finger 14Sc toward the first bonding finger 14Fc is equal to an amount of Cu ions Mc eluted from the second bonding finger 14Sc toward the dummy terminal 100a. This is because the first bonding finger Fc and the dummy terminal 100a are disposed to be spaced apart from the second bonding finger 14Sc by an equal interval W, and each of the first bonding finger Fc and the dummy terminal 100a has been supplied with an equal potential. This causes a uniform electric field to be formed on both sides of the second bonding finger 14Sc, and therefore Cu ions Mc are equally eluted from the second bonding finger 14Sc toward each of the first bonding finger 14Fc and the dummy terminal 100a.

In contrast, as illustrated in FIG. 9, in the semiconductor device in the comparative example, the dummy terminal 100a is not disposed at an end in the negative Y direction of the opening 151.

If the HAST is conducted on the semiconductor device in the comparative example, as described above, a remarkably large amount of Cu ions Mc is eluted, for example, from the second bonding finger 14Sc toward the first bonding finger 14Fc that is located on a side in the positive Y direction in some cases, as illustrated in FIG. 9. This is because the dummy terminal 100a is not disposed on a side in the negative Y direction of the second bonding finger 14Sc. This causes an ununiform electric field to be formed on both sides of the second bonding finger 14Sc, and Cu ions Mc are eluted from the second bonding finger 14Sc toward one side (the side in the positive Y direction) in a concentrated manner. As a result, Cu ions Mc serve as a leakage path, and a short circuit occurs between the second bonding finger 14Sc and the first bonding finger 14Fc in some cases.

### SUMMARY

The semiconductor device 1 according to the embodiment has a configuration in which the first bonding fingers 14F serving as bonding fingers that are connected to the ground potential and the second bonding fingers 14S serving as bonding fingers that are connected to the power supply layer are alternately disposed to be spaced apart from each other by an equal distance. At both ends in the Y direction of the opening 151, two bonding fingers, the first bonding fingers 14Fa and 14Fd, that serve as third bonding fingers are disposed, and the first bonding finger 14Fd is a dummy terminal that is not connected to the semiconductor chip 21.

As described above, at both ends in the Y direction of the second bonding finger 14S, the first bonding finger 14F or the dummy terminal 100a that has been supplied with an equal ground potential is disposed to be spaced apart from the second bonding finger by an equal interval W, and therefore an amount of Cu ions Mc to be eluted from the second bonding finger 14S can be equally distributed to both sides in the Y direction. This reduces an amount of Cu ions Mc to be eluted from one side of the second bonding finger 14S, and this can prevent a short circuit from occurring between the first bonding finger 14F and the second bonding finger 14S. As a result, the semiconductor device 1 can have a longer lifetime.

### First Variation

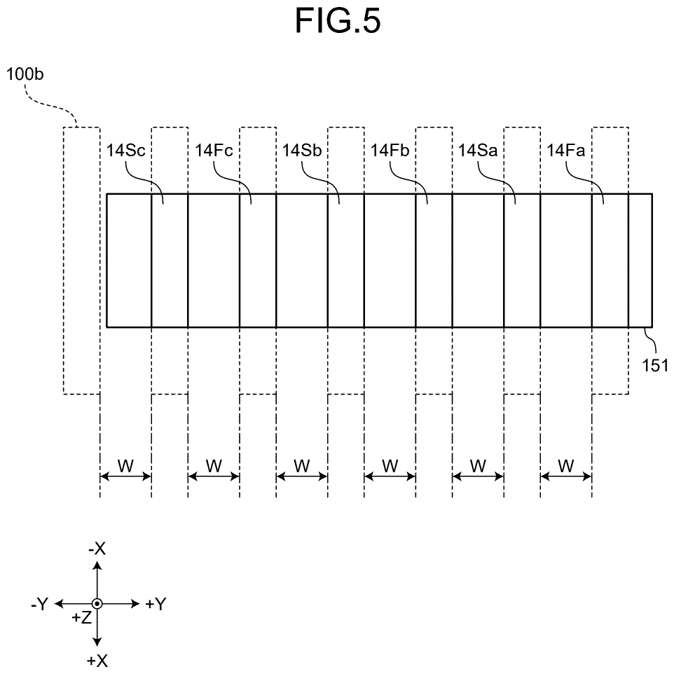

A semiconductor device according to a first variation will be described with reference to FIG. 5. The semiconductor device according to the first variation is different from the embodiment described above in that the entirety of a dummy terminal is covered with the solder resist layer 15. Note that in the description below, a configuration that is similar to a configuration according to the embodiment described above is denoted by a similar reference sign, and the description thereof is omitted in some cases.

FIG. 5 is a partial top view illustrating a configuration around the opening 151 of the semiconductor device according to the first variation. Furthermore, in FIG. 5 and the drawings that follow, a configuration of the bonding wire 51 or the like is omitted.

As illustrated in FIG. 5, in the semiconductor device according to the first variation, a dummy terminal 100b is covered with the solder resist layer 15 (see FIGS. 1 to 3). Stated another way, the dummy terminal 100b is not exposed in the opening 151.

As a result of this, the plated layer MEa and the plated layer MEb are not formed on the dummy terminal 100b. This enables a further reduction in consumption of a plating solution.

Furthermore, even in a case where the dummy terminal 100b is covered with the solder resist layer 15, a uniform electric field is formed on both sides in the Y direction of the second bonding finger 14Sc. This is because the first bonding finger 14Fc and the dummy terminal 100b have been supplied with an equal potential, and the first bonding finger 14Fc and the dummy terminal 100b are disposed to be spaced apart from the second bonding finger 14Sc by an equal interval W. This can prevent a short circuit from occurring between the first bonding finger 14F and the second bonding finger 14S.

### Second Variation

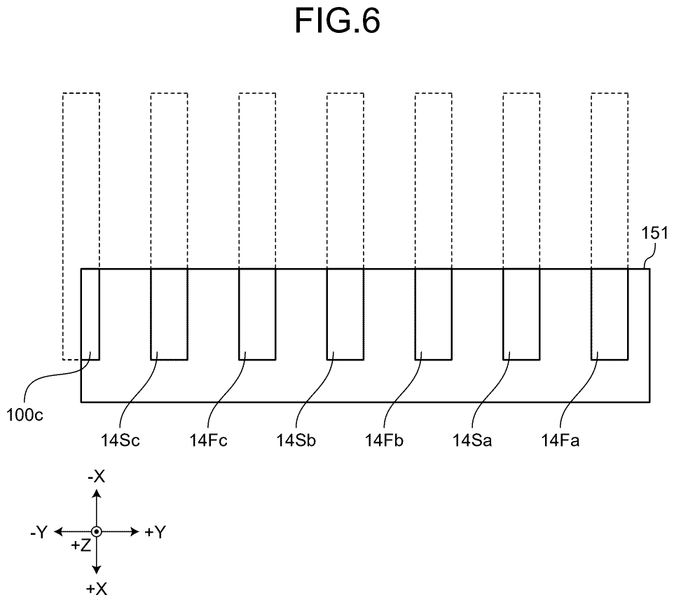

A semiconductor device according to a second variation will be described with reference to FIG. 6. The semiconductor device according to the second variation is different from the embodiment described above in that in the bonding fingers 14, one end in the X direction is exposed in the opening 151. Note that in the description below, a configuration that is similar to a configuration according to the embodiment described above is denoted by a similar reference sign, and the description thereof is omitted in some cases.

FIG. 6 is a partial top view illustrating a configuration around the opening 151 of the semiconductor device according to the second variation.

As illustrated in FIG. 6, in the first bonding fingers 14Fa to 14Fc, a dummy terminal 100c, and the second bonding fingers 14Sa to 14Sc, one end in the X direction is exposed in the opening 151. Stated another way, each of the first bonding fingers 14Fa to 14Fc, the dummy terminal 100b, and the second bonding fingers 14Sa to 14Sc is not entirely exposed in the X direction of the opening 151. Therefore, an exposed area of the core layer COR to be plated is reduced, and this enables a reduction in consumption of a plating solution.

### Third Variation

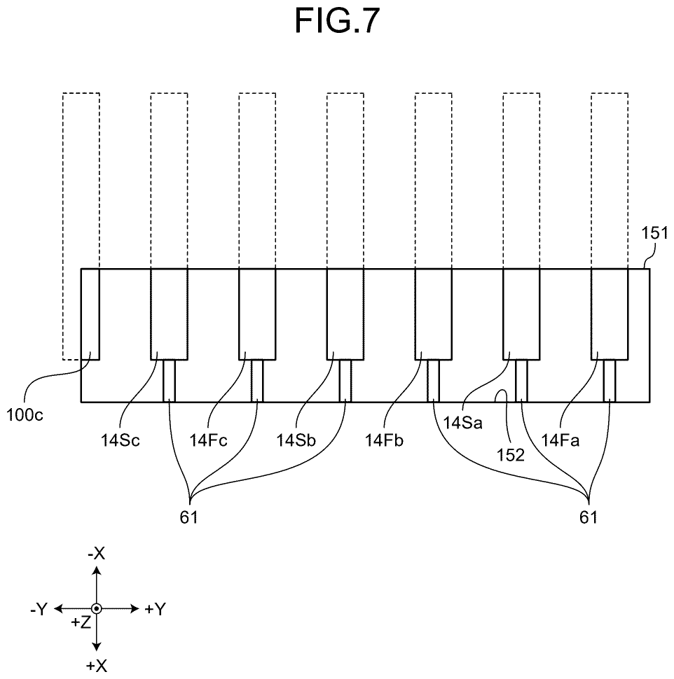

A semiconductor device according to a third variation will be described with reference to FIG. 7. The semiconductor device according to the third variation is a variation that corresponds to the second variation, and is different from the embodiment described above and the second variation in that in the bonding finger 14, one end that is exposed in the opening 151 is connected to a plating lead. Note that in the description below, a configuration that is similar to a configuration according to the embodiment described above is denoted by a similar reference sign, and the description thereof is omitted in some cases.

FIG. 7 is a partial top view illustrating a configuration around the opening 151 of the semiconductor device according to the third variation.

As illustrated in FIG. 7, in the semiconductor device according to the third variation, ends that are exposed in the opening 151 of the first bonding fingers 14Fa to 14Fc, the dummy terminal 100c, and the second bonding fingers 14Sa to 14Sc are connected to a plating lead 61. The plating lead 61 extends along the X direction from an end that is exposed in the opening 151 of each of the bonding fingers, and terminates, for example, in a position that reaches a side face 152 of the opening 151. A width in the Y direction of the plating lead 61 is set to be smaller than a width in the Y direction of each of the first bonding fingers 14Fa to 14Fc, the dummy terminal 100c, and the second bonding fingers 14Sa to 14Sc.

Note that a relationship between the width in the Y direction of the plating lead 61 and the width in the Y direction of each of the first bonding fingers 14Fa to 14Fc, the dummy terminal 100c, and the second bonding fingers 14Sa to 14Sc is not limited to the example of FIG. 7. For example, it is sufficient if, in at least one plating lead 61 from among a plurality of plating leads 61 that is respectively connected to the first bonding fingers 14Fa to 14Fc, the dummy terminal 100c, and the second bonding fingers 14Sa to 14Sc, a width in the Y direction is set to be smaller than a width in the Y direction of a bonding finger that is connected to the corresponding plating lead 61.

As described above, in electroplating, a not-illustrated plating solution and the plating lead 61 are used. In performing electroplating, in the plating leads 61, one end on an opposite side of a side that is connected to each of the bonding fingers 14 is connected to a not-illustrated external device or the like, and a predetermined voltage is supplied to each of the bonding fingers 14. After electroplating has been completed, for example, the plating leads 61 are disconnected in positions that reach the side face 152. This causes each of the bonding fingers to be electrically separated from each other.

Note that FIG. 7 illustrates an example where the plating leads 61 are disconnected in positions that reach the side face 152 of the opening 151, but the places of disconnection of the plating leads 61 are not limited to this.

### Fourth Variation

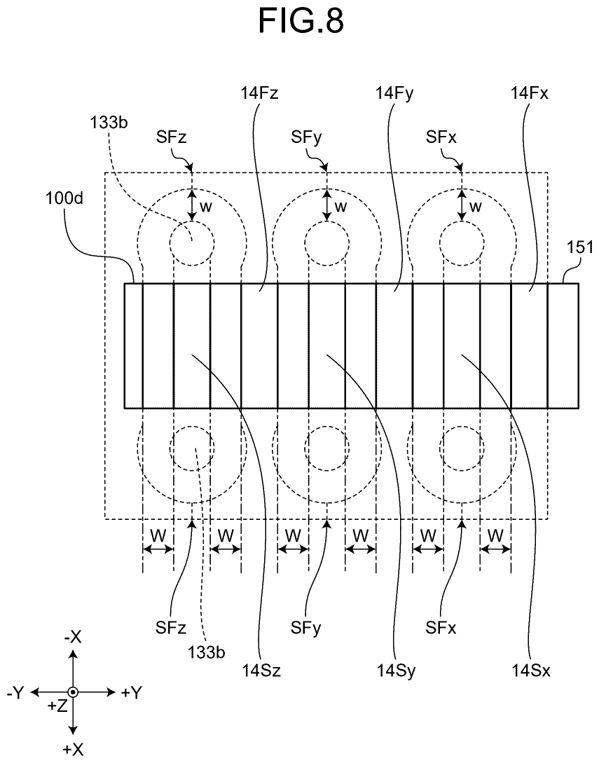

A semiconductor device according to a fourth variation will be described with reference to FIG. 8. In the embodiment described above, the plurality of bonding fingers 14 is arranged along the Y direction to be spaced apart from each other by the equal interval W, and is formed in a finger shape that extends in the X direction. Stated another way, ends in the X direction of adjacent bonding fingers are separated from each other. In contrast, the semiconductor device according to the fourth variation is different from the embodiment described above in that ends in the X direction of the second bonding fingers are in contact with each other. Note that in the description below, a configuration that is similar to a configuration according to the embodiment described above is denoted by a similar reference sign, and the description thereof is omitted in some cases.

FIG. 8 is a partial top view illustrating a configuration around the opening 151 of the semiconductor device according to the fourth variation.

As illustrated in FIG. 8, around the opening 151 of the semiconductor device according to the fourth variation, first bonding fingers 14Fx to 14Fz, a dummy terminal 100d, and second bonding fingers 14Sx to 14Sz are alternately disposed to be spaced apart from each other by an interval W. Furthermore, at both ends in the X direction of the second bonding fingers 14Sx to 14Sz, a via 133b is disposed.

Specifically, as illustrated in FIG. 8, for example, the first bonding finger 14Fx and the first bonding finger 14Fy are disposed on both sides in the Y direction of the second bonding finger 14Sx, the first bonding finger 14Fy and the first bonding finger 14Fz are disposed on both sides in the Y direction of the second bonding finger 14Sy, and the first bonding finger 14Fz and the dummy terminal 100d are disposed on both sides in the Y direction of the second bonding finger 14Sz.

In this case, two first bonding fingers that are disposed on both sides in the Y direction of each of the second bonding fingers 14Sx to 14Sz are connected at both ends in the X direction. Specifically, for example, the first bonding fingers 14Fx and 14Fy are in contact with each other in a boundary SFx at both ends in the X direction of the first bonding fingers 14Fx and 14Fy, the first bonding fingers 14Fy and 14Fz are in contact with each other in a boundary SFy at both ends in the X direction of the first bonding fingers 14Fy and 14Fz, and the first bonding finger 14Fz and the dummy terminal 100d are in contact with each other in a boundary SFz at both ends in the X direction of the first bonding finger 14Fz and the dummy terminal 100d. This causes the second bonding fingers 14Sx to 14Sz to be sandwiched by the first bonding fingers 14Fx to 14Fz and the dummy terminal 100d from both sides in the X direction. The boundaries SFx to SFz where the first bonding fingers are in contact with each other are disposed in positions that are separated from the via 133b in the X direction by the interval W.

As described above, the second bonding fingers 14Sx to 14Sz are sandwiched by the first bonding fingers 14Fx to 14Fz and the dummy terminal 100d from both sides in the X direction and the Y direction to be spaced apart from each other by an equal distance, and therefore a uniform electric field is formed on each of both sides in the X and Y directions of the second bonding fingers 14Sx to 14Sz. As a result of this, Cu ions Mc to be eluted from the second bonding fingers 14Sx to 14Sz are equally distributed to both sides in the X and Y directions, and therefore an amount of elution from one side is reduced. This can more effectively prevent a short circuit from occurring between the first bonding finger and the second bonding finger.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip; and
a wiring board, the semiconductor chip and an insulating layer having an opening being disposed on a first face of the wiring board, the wiring board including a plurality of bonding fingers, a power supply layer, and a ground layer, the plurality of bonding fingers being arranged along a first direction that is a longitudinal direction of the opening and being electrically connectable to the semiconductor chip in the opening, the power supply layer and the ground layer being between the first face and a second face located on an opposite side of the first face, the power supply layer supplying a power supply voltage to the semiconductor chip, the ground layer supplying a ground potential to the semiconductor chip, wherein
the plurality of bonding fingers includes first bonding fingers and second bonding fingers that are alternately arranged to be spaced apart from each other by an equal distance, the first bonding fingers being connected to the ground layer, the second bonding fingers being connected to the power supply layer, each of two third bonding fingers disposed at both ends in the first direction of the opening among the plurality of bonding fingers is the first bonding finger, and one of the two third bonding fingers is a dummy terminal that is not connected to the semiconductor chip.

2. The semiconductor device according to claim 1, wherein
at least a portion of the dummy terminal is covered with the insulating layer.

3. The semiconductor device according to claim 2, wherein
the portion of the dummy terminal covered with the insulating layer is one end in the first direction of the dummy terminal.

4. The semiconductor device according to claim 1, wherein
the semiconductor chip and the plurality of bonding fingers are connected to each other through a bonding wire.

5. The semiconductor device according to claim 1, wherein
both ends of the plurality of bonding fingers in a second direction that intersects the first direction and is along the first face are covered with the insulating layer.

6. The semiconductor device according to claim 5, wherein
the plurality of bonding fingers is formed in a rectangular shape having a longitudinal direction in the second direction.

7. The semiconductor device according to claim 1, wherein
an upper face of the insulating layer is located above upper faces of the plurality of bonding fingers.

8. The semiconductor device according to claim 1, wherein
each of the plurality of bonding fingers includes a core layer, a first plated layer, and a second plated layer, the core layer containing a conductive material, the first plated layer being formed on the core layer, the second plated layer being formed on the first plated layer.

9. The semiconductor device according to claim 1, wherein
the dummy terminal is covered with the insulating layer.

10. The semiconductor device according to claim 1, wherein
one ends of the plurality of bonding fingers in a second direction that intersects the first direction and is along the first face are exposed in the opening.

11. The semiconductor device according to claim 10, wherein
the one ends of the plurality of bonding fingers exposed in the opening are individually connected to plating leads.

12. The semiconductor device according to claim 11, wherein
a width of at least one in the first direction among the plating leads is set to be smaller than a width in the first direction of the bonding finger connected to at least the one plating lead.

13. The semiconductor device according to claim 1, wherein
two of the first bonding fingers disposed on both sides of the second bonding finger are in contact with each other at both ends in a second direction that intersects the first direction and is along the first face.

14. The semiconductor device according to claim 13, wherein
a via that is connected to the power supply layer is connected to both ends in the second direction of the second bonding finger.

15. The semiconductor device according to claim 14, wherein
a boundary in which the two of the first bonding fingers are in contact with each other is separated from the via in the second direction by a distance that is equal to a distance in the first direction between the first bonding finger and the second bonding finger.
